(19) United States
(12) Patent Application Publication
(10) Pub. No.: US 2024/0249920 A1
(43) Pub. Date: Jul. 25, 2024

(54) REMOVABLE MASK LAYER TO REDUCE OVERHANG DURING RE-SPUTTER PROCESS IN PVD CHAMBERS

(71) Applicant: Applied Materials, Inc., Santa Clara, CA (US)

(72) Inventors: Wenting HOU, Sunnyvale, CA (US); Jianxin LEI, Fremont, CA (US)

(21) Appl. No.: 18/099,039

(22) Filed: Jan. 19, 2023

(51) Int. Cl. H01J 37/32

(52) U.S. Cl. CPC H01J 37/32366; H01J 37/3244; H01J 2237/332; H01J 2237/3342

(57) ABSTRACT

Apparatus and methods for processes of depositing a film on a substrate in an electronic device fabrication process are provided herein, and more particularly, apparatus and methods for improving deposited film uniformity within high aspect ratio features. In some embodiments, a metal layer deposition process is performed to deposit a metal layer in a feature definition formed in a substrate. A mask layer deposition process is performed to deposit a carbon layer on the metal layer. Following the mask layer deposition process, a resputtering process is performed by applying a radio frequency (RF) signal to the substrate in a presence of an inert gas. Following performing the resputtering process, an etching process is performed to remove the carbon.

### BACKGROUND

### Field

Embodiments of the present disclosure generally relate to processes for depositing a film on a substrate in an electronic device fabrication process, and more particularly, to apparatus and methods for improving deposited film uniformity within high aspect ratio features.

### Description of the Related Art

Integrated circuits may include more than one million micro-electronic field effect transistors (e.g., complementary metal-oxide-semiconductor (CMOS) field effect transistors) that are formed on a substrate (e.g., semiconductor wafer) and cooperate to perform various functions within the circuit. Reliably producing sub-half micron and smaller features is one of the key technologies for the next generation of very large scale integration (VLSI) and ultra large-scale integration (ULSI) of semiconductor devices. However, as the limits of integrated circuit technology are pushed, the shrinking dimensions of interconnects in VLSI and ULSI technology have placed additional demands on processing capabilities. Reliable formation of the gate pattern is important to integrated circuits success and to the continued effort to increase circuit density and quality of individual substrates and die.

As feature sizes have become smaller, the demand for higher aspect ratios, defined as the ratio between the depth of the feature and the width of the feature, has steadily increased to 20:1 and even greater. A variety of problems may occur when depositing metal layers into feature definitions with small geometries, such as geometries having aspect ratios of about 20:1 or smaller. For example, a metal layer deposited using a conventional physical vapor deposition (PVD) process often suffers from poor step coverage, deposited material overhang, and voids formed within the via or trench, for example when the via has a critical dimension of less than 50 nm or has an aspect ratio greater than 10:1. Insufficient deposition on the bottom and sidewalls of the vias or trenches can also result in deposition discontinuity, thereby resulting in device shorting, poor interconnection formation or variability in device performance across a formed IC device or between formed devices.

Moreover, for PVD processes that will deposit a metal layer, for example tungsten (W) on and in high aspect ratio features, sidewall or step coverage may be insufficient if using a single PVD process alone. In particular, PVD processes for trenches, vias, or other higher aspect ratio features may result in inadequate coverage of the sidewall or step at relatively lower ion energies. To provide for increased sidewall and step coverage, a resputter process may be used, where a relatively higher ion energy is provided to sputter previously deposited material from one portion of a substrate to another portion of the substrate. However, while a relatively higher ion energy may result in increased step or sidewall coverage, there is a risk of damage to the sputtered layer (e.g., a metal layer, such as tungsten). Additionally, there is a risk of damage to the substrate (e.g., a dielectric) on which the material is being deposited. Moreover, during re-sputtering, an overhang of the deposited material may build up at the opening of the features. Etching techniques, such as fluorine containing etching chemistries, may be used to remove the overhanging material. However, these techniques may also damage the substrate (e.g., the exposed dielectric) on which the material has been deposited.

Accordingly, there is a need in the art for apparatus and methods for reducing overhang in connection with PVD processes.

### SUMMARY

Embodiments described herein generally relate to physical vapor deposition (PVD) film formation on substrates in an electronic device fabrication process. More particularly, embodiments described herein provide apparatus and methods for reducing overhang in connection with PVD processes.

In one or more embodiments, a processing system includes a first substrate processing chamber, a second substrate processing chamber, one or more transfer chambers coupling the first substrate processing chamber and the second substrate processing chamber, and a system controller. The system controller is configured to control the first substrate processing chamber to perform a metal layer deposition process to deposit a metal layer in a feature definition formed in a substrate. The system controller is further configured to control the first substrate processing chamber or the second substrate processing chamber to perform a mask layer deposition process to deposit a carbon layer on the metal layer. The system controller is further configured to control the first substrate processing chamber, the second substrate processing chamber, or the third substrate processing chamber to perform, following the mask layer deposition process, a resputtering process by applying a radio frequency (RF) signal to the substrate in a presence of an inert gas. The system controller is further configured to control the second substrate processing chamber or the third substrate processing chamber to perform, following the resputtering process, an etching process to remove the carbon layer.

One or more embodiments include a method for depositing a metal layer for a semiconductor device. The method includes performing a metal layer deposition process to deposit a metal layer in a feature definition formed in a substrate. The method also includes performing a mask layer deposition process to deposit a carbon layer on the metal layer. The method also includes performing, following the mask layer deposition process, a resputtering process by applying a RF signal to the substrate in a presence of an inert gas. The method also includes performing, following performing the resputtering process, an etching process to remove the carbon layer.

One or more embodiments include another method for depositing a metal layer for a semiconductor device. The method includes performing a first physical vapor deposition (PVD) process in a first PVD chamber to deposit a tungsten layer in a feature definition formed in a substrate disposed on a pedestal, wherein the pedestal is biased at a first voltage. The method also includes performing a second PVD process in the first PVD chamber or a second PVD chamber to deposit a carbon mask layer on the tungsten layer, where the pedestal is unbiased. The method also includes performing, following the second PVD process, a first etching process in the presence of oxygen or hydrogen to remove carbon from within the feature definition. The method also includes performing, following the first etching process, a resputtering process in a presence of an argon gas or a krypton gas, the resputtering process performed in the first PVD chamber, the second PVD chamber, or a third PVD chamber. The method also includes performing, following the resputtering process, a second etching process in a presence of an oxygen gas or a hydrogen gas to remove the carbon mask layer. The method also includes performing, following the second etching process, a chemical vapor deposition (CVD) process to bulk fill tungsten in the feature definition

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of an exemplary multi-chamber substrate processing system, according to certain embodiments.

FIGS. 2A-2C depict cross-sectional views of a semiconductor device during the formation of a metal layer, according to certain embodiments.

FIGS. 3A-3D depict cross-sectional views of a semiconductor device during the formation of a metal layer according to certain embodiments.

FIG. 4 is a diagram illustrating a method of depositing a metal layer for a semiconductor device, according to certain embodiments.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the disclosure provided herein generally relate to depositing layers on a substrate used to form at least part of a semiconductor device in a substrate processing system, for example using physical vapor deposition (PVD) in an electronic device fabrication process. More particularly, embodiments described herein provide apparatus and methods for improving film deposition uniformity of films or layers within features formed on a substrate using a removable mask layer to reduce overhang during a resputter process. In some embodiments, the apparatus may include a first processing chamber (e.g., a first PVD chamber) in which a first PVD process is performed to deposit a metal layer (e.g., tungsten layer) in a feature definition such as a via or trench formed in a substrate. The substrate may be disposed on a pedestal that is biased at a first voltage during at least a portion of a PVD process. A second PVD process may be performed in a second processing chamber (e.g., second PVD chamber) to deposit a carbon mask layer on the metal layer (e.g., the tungsten layer). In one or more embodiments, the second PVD process may be performed in the first processing chamber. In some embodiments the pedestal on which the substrate is disposed in the second processing chamber is unbiased. A first etching process in the presence of oxygen or hydrogen is then performed to remove carbon from within the feature definition, for example from the sidewall portion and bottom portion of the feature to expose the underlying metal layer for a subsequent resputtering process. Because the carbon mask layer is thicker on the filed region of the substrate, which is outside the feature definition, and the first etching process removes carbon from the sidewall portion and bottom portion of the feature definition while leaving at least some carbon of the carbon mask layer outside the feature definition. Following the first etching process, a resputtering process is performed in a presence of an inert sputter gas (e.g., an argon gas or a krypton gas). The resputtering process may sputter the previously deposited metal (e.g., tungsten) from the bottom portion of the feature definition to the sidewalls of the feature definition. Additionally, as a result of the resputtering process, the carbon of the carbon mask layer may form overhanging portions, which include carbon material that overhangs the feature definition, for example reducing a diameter of an aperture of a via (in the case of the feature definition being a via structure) or a width of a trench (in the case of the feature definition being a trench structure). In one or more embodiments, the resputtering process may be performed in the first processing chamber of the substrate processing system used to deposit the tungsten layer, the second processing chamber of the substrate processing system used to deposit the carbon mask layer, or a third and different processing chamber of the substrate processing system. Following the resputtering process, in one or more embodiments, a second etching process is performed to remove the carbon mask layer. The second etching process is performed in a presence of an oxygen gas or a hydrogen gas to remove the carbon mask layer. In one or more embodiments, the second etching process may be performed in the second processing chamber or the third processing chamber. Finally, a chemical vapor deposition (CVD) process may be performed to bulk fill a metal (e.g., tungsten) in the feature definition, the metal layer that was formed acting as a seed layer for the metal that fills the features as a result of the CVD process. The one or more embodiments described herein may reduce overhang in connection with PVD processes, for example for high aspect ratio feature definitions, and reduce or eliminate damage to substrates when reducing such overhang.

### Exemplary Substrate Processing System

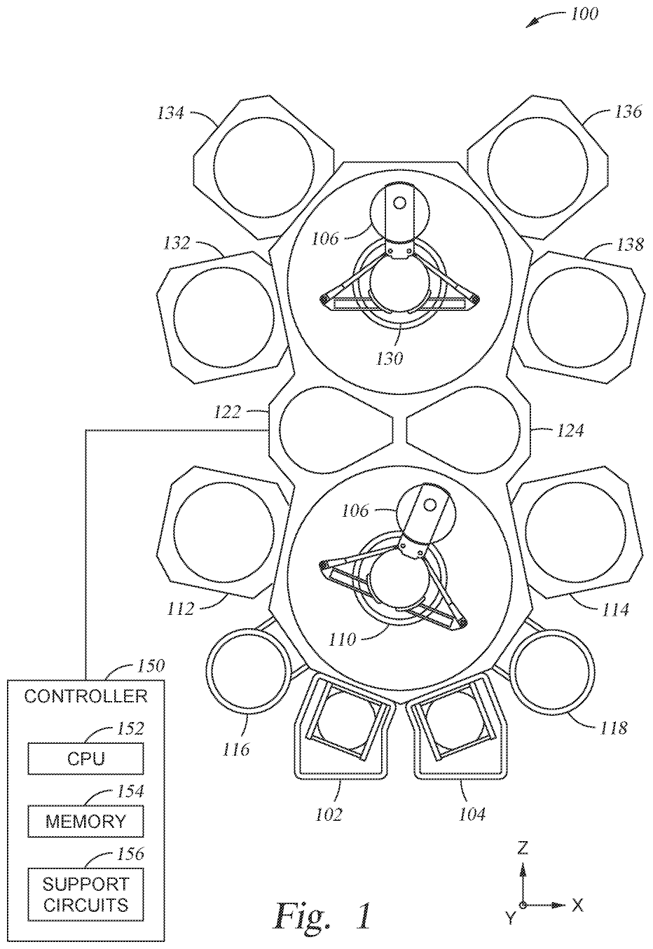

FIG. 1 is a schematic top view diagram of an illustrative multi-chamber processing system 100 that can be adapted to perform a metal layer deposition process as disclosed herein. The system 100 can include one or more load lock chambers 102 and 104 for transferring substrate 106 into and out of the system 100. Generally, the system 100 is maintained under vacuum and the load lock chambers 102 and 104 can be “pumped down” to introduce substrate 106 introduced into the system 100. A first robot 110 can transfer the substrate 106 between the load lock chambers 102 and 104, and a first set of one or more substrate processing chambers 112, 114, 116, and 150. Each processing chamber 112, 114, 116, and 150 is configured to be at least one of a substrate deposition process, such as cyclical layer deposition (CLD), atomic layer deposition (ALD), chemical vapor deposition (CVD), physical vapor deposition (PVD), etch, degas, pre-cleaning orientation, anneal, and other substrate processes. Furthermore, one of the processing chambers 112, 114, 116, and 150 may also be configured to perform a pre-clean process prior to performing a deposition process or a thermal annealing process on the substrate 106. The position of the processing chamber 150 utilized to perform a thermal annealing process relative to the other chambers 112, 114, 116 is for illustration, and the position of the processing chamber 150 may be optionally be switched with any one of the processing chambers 112, 114, 116 if desired.

The first robot 110 can also transfer substrate 106 to/from one or more transfer chambers 122 and 124. The transfer chambers 122 and 124 can be used to maintain ultrahigh vacuum conditions while allowing substrate 106 to be transferred within the system 100. A second robot 130 can transfer the substrate 106 between the transfer chambers 122 and 124 and a second set of one or more processing chambers 132, 134, 136 and 138. Similar to the processing chambers 112, 114. 116, and 150, the processing chambers 132, 134, 136, and 138 can be outfitted to perform a variety of substrate processing operations including the dry etch processes described herein in addition to cyclical layer deposition (CLD), atomic layer deposition (ALD), chemical vapor deposition (CVD), physical vapor deposition (PVD), etch, pre-clean, degas, and orientation, for example. Any of the substrate processing chambers 112, 114, 116, 132, 134, 136, and 138 can be removed from the system 100 if not necessary for a particular process to be performed by the system 100. After the preclean, deposition and/or a thermal annealing process is performed in the processing chamber 150, the substrate may further be transferred to any of the processing chambers 112, 114, 116, 132, 134, 136, and 138 of the system 100 to perform other process as needed.

A system controller 140, such as a programmable computer, is coupled to the remainder of the system 100, or components thereof. For example, the system controller 140 may control the operation of one or more of substrate processing chambers 112, 114, 116, 132, 134, 136, 138, and 150, first robot 110, second robot 130, load lock chamber 102, and/or load lock chamber 104, or using indirect control of other controllers associated therewith. In operation, the system controller 140 enables data acquisition and feedback to coordinate processing in the one or more substrate processing chambers 112, 114, 116, 132, 134, 136, 138, and 150.

The system controller 140 includes a programmable central processing unit (CPU) 142, which is operable with a memory 144 (e.g., non-volatile memory) and support circuits 146. The support circuits 146 (e.g., cache, clock circuits, input/output subsystems, power supplies, etc., and combinations thereof) are conventionally coupled to the CPU 142 and coupled to the various other components of the system 100.

In some embodiments, the CPU 142 is one of any form of general purpose computer processor used in an industrial setting, such as a programmable logic controller (PLC), for controlling various monitoring system component and sub-processors. The memory 144, coupled to the CPU 142, is non-transitory and is typically one or more of readily available memory such as random access memory (RAM), read only memory (ROM), floppy disk drive, hard disk, or any other form of digital storage, local or remote.

Herein, the memory 144 is in the form of a computer-readable storage media containing instructions (e.g., non-volatile memory), that when executed by the CPU 142, facilitates the operation of the system 100. The instructions in the memory 144 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Exemplary Metal Layer Formation

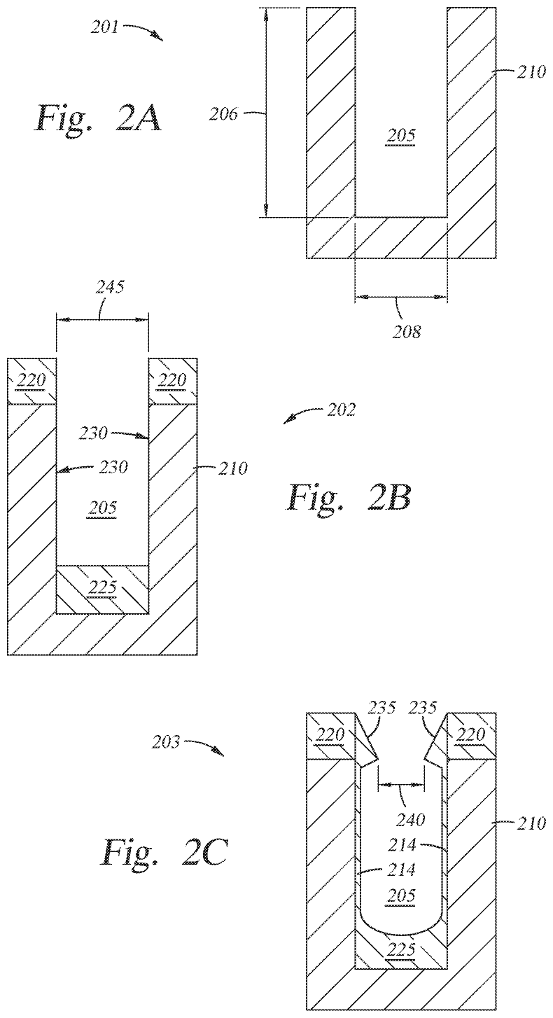

FIGS. 2A-2C depict cross-sectional views of a semiconductor device during the formation of a metal layer, according to certain embodiments. FIGS. 2A-2C depict a substrate 210 during a set of fabrication stages to deposit a metal layer in a feature definition 205 formed in the substrate 210, generally proceeding from stage 201 followed by stage 202 followed by stage 203.

At stage 201, a substrate 210 is provided with at least one feature definition 205 provided therein. Feature definitions include high aspect ratio features, such as vias or trenches, where the ratio of height 206 of the feature to width 208 of the feature is typically 5:1 or greater, such as 10:1 or 20:1. Although not shown at stage 201, substrate 210 may have previously formed on it one or more layers or structures, such that substrate 210 is not of a homogenous material.

At stage 202, a metal layer is formed on substrate 210, including in feature definition 205. In one or more embodiments, the metal layer is tungsten (W), though the techniques described herein may be applied to other materials, for example a pure material or alloy containing elements selected from the group of copper (Cu), molybdenum (Mo), nickel (Ni), titanium (Ti), tantalum (Ta), aluminum (Al), cobalt (Co), gold (Au), silver (Ag), manganese (Mn), and silicon (Si). In one or more embodiments, the metal layer is formed using a PVD process.

The formed metal layer includes top portions 220, which is formed on a “field region” of a substrate, and bottom portions 225. The top portions 220 are on substrate 210 outside of feature definition 205 and bottom portion 225 of the metal layer formed on substrate 210 within feature definition 205. In one example, the metal layer deposition process is a first PVD process, for example sputtering of a metal target. The metal layer deposition process deposits the metal (e.g., tungsten) on the substrate, both outside of and within feature definition 205 on the substrate, including on a bottom portion 225. The metal layer deposition will also provide some deposition on sidewall portion 230. However, the coverage of the metal layer for sidewall portion 230 following the first PVD process may be of inadequate thickness for the metal layer. For example, the first PVD process may use a relatively higher energy sputtering of the metal target to deposit the metal layer at stage 202, which may result in relatively faster deposition of the metal material on the substrate 210, but relatively less material being deposited on the sidewall portion 230. For example, higher energy sputtering may result in a relatively faster deposition process than a lower energy sputtering process, but may have less deposition within the feature definition 205. In some cases, as shown in FIG. 2B, the material deposited at stage 202 may result in metal material on the sidewall portion 230 being absent, discontinuous, or otherwise be inadequately formed.

At stage 203, a resputtering process is performed to deposit additional metal material on the sidewall portion 214 of the metal layer. The resputtering process results in removal of at least some material of the bottom portion 225, resulting in erosion of the bottom portion 225, as well as overhang portions 235 for the top portions 220. In particular, during the resputtering process additional metal material (e.g., tungsten) may be deposited on sidewall portions 214, while some material is removed from bottom portion 225, for example re-deposited on sidewall portions 214. Additionally, the resputtering process may result in the creation of overhanging portions 235 of the metal layer. The resulting overhanging portions 235 may be difficult to remove. For example, fluorochemistry that may be used to remove portions of the metal layer (e.g., tungsten) may also result in damage to the substrate (e.g., the dielectric). Additionally, following stage 203, the aperture 240 for width 208 of feature definition 205 may be a smaller or substantially smaller size than the aperture 245 formed at the opening of the feature definition 205 at stage 202, which will adversely affect the subsequent feature filling process(es).

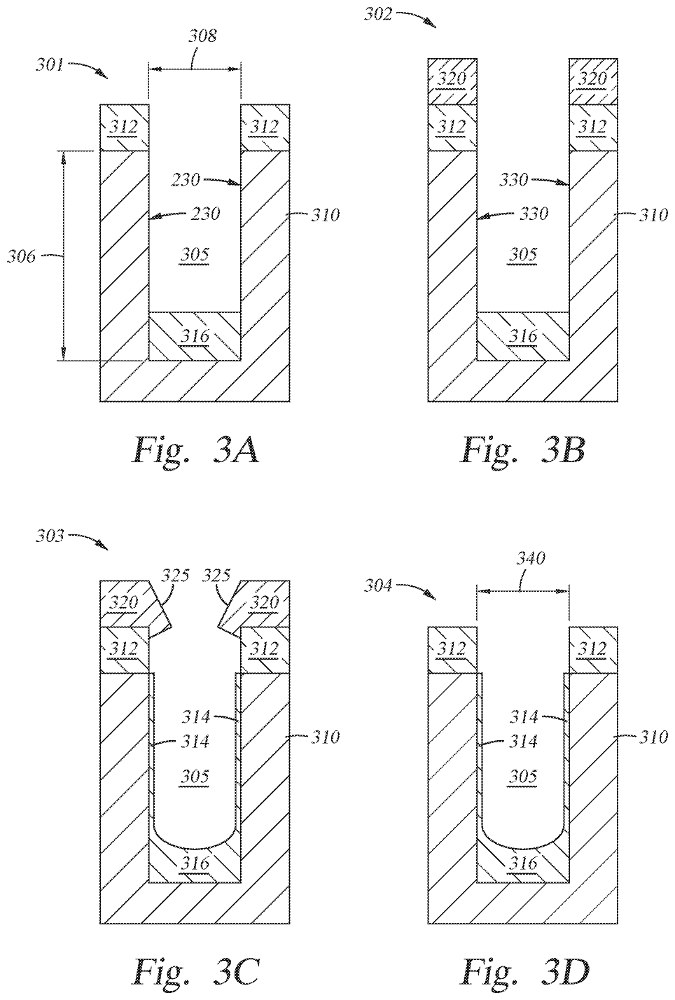

FIGS. 3A-3D depict cross-sectional views of a semiconductor device during the formation of a metal layer, according to certain embodiments. FIGS. 3A-3D depict a substrate 310 during a set of fabrication stages to deposit a metal layer in a feature definition 305 formed in the substrate 310, generally proceeding from stage 301 followed by stage 302 followed by stage 303 followed by stage 304.

At stage 301, a metal layer is formed on substrate 310, including in feature definition 305. The metal layer is formed on a substrate 310 that is provided with at least one feature definition 305 provided therein. Feature definitions include high aspect ratio features, such as vias or trenches, where the ratio of height 306 of the feature to width 308 of the feature is typically 5:1 or greater, such as 10:1 or 20:1. Although not shown at stage 301, substrate 310 may have previously formed on it one or more layers or structures, such that substrate 310 is not of a homogenous material.

In one or more embodiments, the formed metal layer includes top portions 312 and bottom portion 316. The top portions 312 are on substrate 310 outside of feature definition 305 and bottom portion 316 of the metal layer formed on substrate 310 within feature definition 305. In some embodiments, the metal layer deposition process is a first PVD process, for example sputtering of a metal target. The metal layer deposition process deposits the metal, which may be tungsten (W) in one or more embodiments, on the substrate, both outside of and within feature definition 305 on the substrate, including on a bottom portion 316. The metal layer deposition will also provide some deposition on sidewalls 330. However, the coverage of the metal layer for sidewalls 330 following the first PVD process may be of inadequate thickness for the metal layer. For example, the first PVD process may use a relatively higher energy sputtering of the metal target to deposit the metal layer at stage 301, which may result in relatively faster deposition of the metal material on the substrate 310, but relatively less material being deposited on the sidewalls 330. For example, higher energy sputtering may result in a relatively faster deposition process than a lower energy sputtering process, but may have less deposition within the feature definition 305. In some cases, the material deposited at stage 301 may result in metal material on the sidewalls 330 being absent, discontinuous, or otherwise be inadequately formed.

In one or more embodiments, the metal layer deposition process may include a PVD deposition process that applies a DC signal of between about 35 KW to 60 KW (e.g., 35 KW) to a metal containing target (e.g., a tungsten containing target), an RF bias of between about 0 W to 1000 W (e.g., 300 W) (e.g., 13.56 MHZ) applied to an electrode disposed in a substrate support, using a flow rate to achieve a process pressure of less than about 1 millitorr, for between about 10 seconds to 30 seconds (e.g., about 20 seconds). In one or more embodiments, between about 60 Å to 200 Å (e.g., about 150 Å) of tungsten may deposited for top portion 312 of the metal layer.

In one or more embodiments, the metal layer is tungsten (W), though the techniques described herein may be applied to other materials, for example a pure material or alloy containing elements selected from the group of copper (Cu), molybdenum (Mo), nickel (Ni), titanium (Ti), tantalum (Ta), aluminum (Al), cobalt (Co), gold (Au), silver (Ag), manganese (Mn), and silicon (Si).

In one or more embodiments, during stage 301, a voltage bias is applied to a pedestal supporting the substrate 310 during the PVD process to increase the quantity and density of metal ions and gas ions, that interact with the surface of the substrate including within feature definition 305. In particular, a greater density of ions during the metal layer deposition process increases the quantity of material deposited on the sidewalls 330. In one or more embodiments, the sputtering gas, and thus the sputtering ions, may be argon or krypton. Other inert gases may be used in other embodiments, including neon, xenon, or nitrogen.

At stage 302 a mask layer 320 formed of mask material is deposited on the metal layer during a mask layer deposition process. The mask layer 320 may also be referred to as a capping layer. In one or embodiments, the mask material layer includes carbon. In one or embodiments, the mask material layer includes amorphous carbon or microcrystalline carbon. The mask layer 320 is deposited to protect the metal layer during subsequent processing steps and/or prevent the formation of overhanging features in the metal layer during resputtering.

In one or more embodiments, the mask layer deposition process may include a PVD deposition process that applies a DC signal of between about 1 KW to 5 KW (e.g., about 3 kW) to a carbon containing target, an RF bias of between about 0 W to 100 W (e.g., about 50 W) (e.g., 13.56 MHZ) applied to an electrode disposed in a substrate support, with an argon gas flow rate of between about 10 SCCM to 100 SCCM (e.g., about 30 SCCM) to achieve a process pressure of between about 0.5 millitorr to 5 millitorr for between about 10 seconds to 100 seconds (e.g., about 45 seconds). The carbon containing target may comprise an amorphous carbon or polycrystalline target material. In one or more embodiments, between about 50 Å to 200 Å (e.g., about 130 Å) of carbon may deposited for top portion 312 of the metal layer.

In one or more embodiments, the mask layer deposition process at stage 302 may be performed in a different substrate processing chamber than the metal layer deposition process at stage 301. For example, the metal layer deposition process may be performed in a first substrate processing chamber of the system 100 and the mask layer deposition process may be performed in a different substrate processing chamber of the system 100.

In one or more embodiments, the following the mask layer deposition process, the mask layer 320 is optionally etched to remove mask material that may have been deposited on the sidewall portions 314 or a surface 321 of the bottom portion 316 of the metal layer during the stage 302. In one or more embodiments, oxygen (O) or hydrogen (H) may be used during the etching procedure to remove the unwanted deposited carbon material. Oxygen and hydrogen may preferentially etch the mask layer (e.g., formed of carbon) over the metal layer (e.g., formed of tungsten), removing the unwanted mask material of the mask layer at a greater rate than the metal material of the metal layer. In other embodiments a different etching gas may be used, for example other gases that preferentially etches carbon over tungsten. In some embodiments, using hydrogen during the etching procedure may reduce an amount of formation of tungsten oxide (WOx) formed (e.g., relative to using oxygen for the etching procedure), and using hydrogen gas may provide for a thermal reduction of the oxide without the need for the generation of a plasma.

In one or more embodiments, an oxygen etch process may use an RF bias of between about 100 W to 1000 W (e.g., about 50 W) (e.g., 13.56 MHZ) applied to an electrode disposed in a substrate support with an oxygen gas flow rate of between about 100 SCCM to 500 SCCM (e.g., about 200 SCCM) for between about 10 seconds to 50 seconds. In one or more embodiments, between about 10 Å to 50 Å (e.g., about 10 Å) of carbon may be etched away.

The optional stage of etching the mask material may be performed in a substrate processing chamber of the system 100 in one or more embodiments. For example, the optional etching of the mask layer following the mask layer deposition process may be performed in the same substrate processing chamber as the mask layer deposition process, or the first substrate processing chamber for the metal layer deposition process, or a different substrate processing chamber, such as a chamber of system 100 also used for a precleaning process for the substrate.

At stage 303, a resputtering process is performed. The resputtering process results in removal or redistribution of at least some material of the bottom portion 316, resulting in erosion of the bottom portion 316, as well creating overhanging portions 325 for the masking layer. In particular, during the resputtering process additional metal material (e.g., tungsten) may be deposited on sidewall portions 314 by the resputtering of material from the bottom portion 316 to the sidewall portions 314. Additionally, the resputtering process may result in the creation of overhanging portions 325 of the mask layer 320 by the resputtering of the mask material from the mask layer 320 to the overhanging portions. The mask material of the mask layer 320 may protect the top portion 312 of the metal layer from being resputtering at stage 302.

In one or more embodiments, the resputtering process may use a first RF bias of between about 500 W to 1 KW (e.g., about 1 KW) (e.g., 13.56 MHZ) and a second RF bias of between about 0 W to 1 KW (e.g., about 400 W) (e.g., 40 MHZ) that are applied to the electrode disposed in a substrate support with a krypton or argon gas flow rate of between about 5 SCCM to 200 SCCM (e.g., about 7 SCCM) to achieve a process pressure of between about 0.5 millitorr to 20 millitorr for between about 3 seconds to 10 seconds (e.g., about 5.1 seconds), where the selectivity for the resputtering between the carbon and tungsten may be about 5:1. In one or more embodiments, the first RF bias or the second RF bias, or both, may be applied to the substrate only, to achieve the formation of a capacitively coupled plasma (CCP) between the substrate and the target. In one or more embodiments, krypton may provide improved selectivity for tungsten relative to argon.

Following the resputtering process at stage 303, at stage 304, the mask material (e.g., carbon) of the mask layer 320, including the overhanging portions 325, may be etched to remove the mask material. In one or more embodiments, oxygen (O) or hydrogen (H) may be used for the etching procedure. Oxygen and hydrogen may preferentially etch the mask layer (e.g., formed of carbon) over the metal layer (e.g., formed of tungsten). In other embodiments a different etching gas may be used, for example other gases that preferentially etch carbon over tungsten.

In one or more embodiments, an oxygen etch process may use an RF bias of between about 100 W to 1000 W (e.g., about 50 W) (e.g., 13.56 MHZ) with an oxygen gas flow rate of between about 100 SCCM to 500 SCCM (e.g., about 200 SCCM) for between about 10 seconds to 50 seconds. In one or more embodiments, all or substantially all the remaining carbon of the mask layer may be removed, leaving between about 60 Å to 200 Å (e.g., about 150 Å) of tungsten. In one or more embodiments, the RF bias may be applied to the substrate only, to achieve the formation of a capacitively coupled plasma (CCP) between the substrate and the target.

Following stage 303, a metal layer (e.g., tungsten layer) is formed on the substrate 310, the metal layer including top portions 312, sidewall portions 314, and bottom portions 316, within the feature definition with reduced or exclusive of overhanging portions of the metal layer. For example, the aperture 340 of the feature definition 305 may be larger for a same width of the width 308 as the aperture 240 for width 208 of feature definition 205 described with reference to stage 203.

### Method of Use

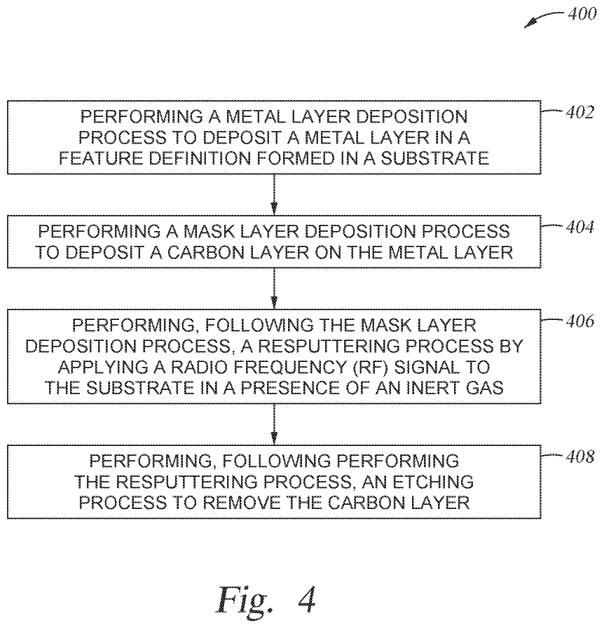

FIG. 4 is a diagram illustrating a method 400 for depositing a metal layer for a semiconductor device, according to certain embodiments. Note that system 100 is described in the following example for illustrative purposes only.

At operation 402, a metal layer deposition process is performed to deposit a metal layer in a feature definition formed in a substrate. In one or more embodiments, the metal layer deposition process is performed at stage 301 to deposit a metal layer as the metal layer in the feature definition 305 formed in the substrate 310, where the metal layer includes at least the top portion 312 and the bottom portion 316. In one or more embodiments, the metal layer deposition process at operation 402 is a physical vapor deposition process. In one or more embodiments, the metal layer is a tungsten layer. In one or more embodiments, operation 402 includes applying a first bias voltage to a pedestal on which the substrate is disposed while performing the metal layer deposition process.

At operation 404, a mask layer deposition process is performed to deposit a carbon layer on the metal layer. In one or more embodiments, the mask layer deposition process is performed at stage 302 to deposit a carbon layer as the mask layer 320 on the metal layer that includes at least the top portion 312 and the bottom portion 316. In one or more embodiments, the metal layer is a tungsten layer. In one or more embodiments, the mask layer deposition process at operation 404 is a physical vapor deposition process. In one or more embodiments, the mask layer deposition process at operation 404 is a physical vapor deposition process that is performed in the same processing chamber as operation 402 or a different processing chamber within the same processing system.

At operation 406, following operation 404, a resputtering process is performed by applying a radio frequency (RF) signal to the substrate in the presence of an inert gas. In one or more embodiments, the resputtering process is performed at stage 303 by applying a RF signal to the substrate 310 in the presence of an inert gas. In one or more embodiments, performing the resputtering process at operation 406 includes applying a first radio frequency (RF) signal power in the presence of the inert gas for a first time duration, and applying a second RF signal power in the presence of the inert gas for a second time duration. In one or more embodiments, the resputtering process at operation 406 is performed in the same processing chamber as operation 402 or 404, or a different processing chamber within the same processing system.

At operation 408, following operation 406, an etching process is performed to remove the carbon layer. In one or more embodiments, the etching process is performed at stage 303 to remove the carbon layer as the masking layer 320, including overhanging portion 325. In one or more embodiments, the etching process at operation 408 is performed in the same processing chamber as operation 402, 404 or 406, or a different processing chamber within the same processing system.

In one or more embodiments, following the mask layer deposition process at operation 404 and before the resputtering process at operation 406, a second etching process is performed to remove carbon from one or more regions within the feature definition.

In one or more embodiments, a chemical vapor deposition process is performed to bulk fill tungsten in the feature definition after performing operation 408. In one or more embodiments, the chemical vapor deposition process is performed to bulk fill tungsten in the feature definition 305.

Additionally, in some embodiments of method 400, one or more operations may be performed between operations 402 and 404, between operations 404 and 406, or between operations 406 and 408.

While the foregoing is directed to embodiments of the present disclosure, other and further embodiments of the disclosure may be devised without departing from the basic scope thereof, and the scope thereof is determined by the claims that follow.

What is claimed is:

1. A processing system, comprising:
a first substrate processing chamber;
a second substrate processing chamber;
one or more transfer chambers coupling the first substrate processing chamber and the second substrate processing chamber; and
a system controller that is configured to control:
the first substrate processing chamber to perform a metal layer deposition process to deposit a metal layer in a feature definition formed in a substrate;
the first substrate processing chamber or the second substrate processing chamber to perform a mask layer deposition process to deposit a carbon layer on the metal layer;
the first substrate processing chamber, the second substrate processing chamber, or a third substrate processing chamber to perform, following the mask layer deposition process, a resputtering process by applying a radio frequency (RF) signal to the substrate in a presence of an inert gas; and
the second substrate processing chamber or the third substrate processing chamber to perform, following the resputtering process, an etching process to remove the carbon layer.

2. The processing system of claim 1, wherein the system controller is further configured to control:
the second substrate processing chamber, the third substrate processing chamber, or a fourth substrate processing chamber to perform, following the mask layer deposition process and before the resputtering process, a second etching process to remove carbon from within the feature definition.

3. The processing system of claim 2, further comprising:
a fifth substrate processing chamber, wherein the system controller is further configured to control the fifth substrate processing chamber to perform a chemical vapor deposition process to bulk fill tungsten in the feature definition.

4. The processing system of claim 2, wherein the metal layer deposition process comprises a physical vapor deposition process.

5. The processing system of claim 4, wherein the system controller is further configured to control the first substrate processing chamber to:
apply a first bias voltage to a pedestal on which the substrate is disposed while performing the metal layer deposition process.

6. The processing system of claim 2, wherein the mask layer deposition process comprises a physical vapor deposition process.

7. The processing system of claim 1, wherein the system controller configured to control the first substrate processing chamber to perform the resputtering process comprises the system controller configured to control the first substrate processing chamber, the second substrate processing chamber, or a third substrate processing chamber to:
apply a first radio frequency (RF) signal power in the presence of the inert gas for a first time duration; and
apply a second RF signal power in the presence of the inert gas for a second time duration.

8. The processing system of claim 1, wherein the system controller controls the first substrate processing chamber to perform the mask layer deposition process.

9. The processing system of claim 1, wherein the system controller controls the second substrate processing chamber to perform the mask layer deposition process.

10. The processing system of claim 1, wherein the inert gas comprises a neon gas, an argon gas, a krypton gas, a xenon gas, or a combination thereof.

11. The processing system of claim 1, wherein the etching process to remove the carbon layer is performed using an oxygen gas.

12. The processing system of claim 1, wherein the etching process to remove the carbon layer is performed using a hydrogen gas.

13. A method for depositing a metal layer for a semiconductor device, comprising:
performing a metal layer deposition process to deposit a metal layer in a feature definition formed in a substrate;
performing a mask layer deposition process to deposit a carbon layer on the metal layer;
performing, following the mask layer deposition process, a resputtering process by applying a radio frequency (RF) signal to the substrate in a presence of an inert gas; and
performing, following performing the resputtering process, an etching process to remove the carbon layer.

14. The method of claim 13, further comprising:
performing, following the mask layer deposition process and before the resputtering process, a second etching process to remove carbon from within the feature definition.

15. The method of claim 13, further comprising:
performing a chemical vapor deposition process to bulk fill a metal in the feature definition.

16. The method of claim 13, wherein the metal layer deposition process comprises a physical vapor deposition process and the metal layer comprises tungsten.

17. The method of claim 16, further comprising:
applying a first bias voltage to a pedestal on which the substrate is disposed while performing the metal layer deposition process.

18. The method of claim 13, wherein the mask layer deposition process comprises a physical vapor deposition process.

19. The method of claim 13, wherein performing the resputtering process comprises:
applying a first radio frequency (RF) signal power in the presence of the inert gas for a first time duration; and
applying a second RF signal power in the presence of the inert gas for a second time duration.

20. A method for depositing a tungsten layer for a semiconductor device, comprising:
performing a first physical vapor deposition (PVD) process in a first PVD chamber to deposit a tungsten layer in a feature definition formed in a substrate disposed on a pedestal, wherein the pedestal is biased at a first voltage;
performing a second PVD process in the first PVD chamber or a second PVD chamber to deposit a carbon mask layer on the tungsten layer, wherein the pedestal is unbiased;
performing, following the second PVD process, a first etching process in the presence of oxygen or hydrogen to remove carbon from within the feature definition;
performing, following the first etching process, a resputtering process in a presence of an argon gas or a krypton gas, the resputtering process performed in the first PVD chamber, the second PVD chamber, or a third PVD chamber;
performing, following the resputtering process, a second etching process in a presence of an oxygen gas or a hydrogen gas to remove the carbon mask layer; and
performing, following the second etching process, a chemical vapor deposition (CVD) process to bulk fill tungsten in the feature definition.
